(19) United States
(12) Patent Application Publication
(10) Pub. No.: US 2006/0096951 A1
(43) Pub. Date: May 11, 2006

(54) APPARATUS AND METHOD FOR CONTROLLING PROCESS NON-UNIFORMITY

(75) Inventors: Wesley C. Natzle, New Paltz, NY (US); William Chu, Hopewell Junction, NY (US); David V. Horak, Essex Junction, VT (US); Arthur H. LaFlamme JR., Rowley, MA (US); Tomoyasu Masayuki JR., Yamanashi (JP); Akihisa Sekiguchi, Briarcliff Manor, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignees: INTERNATIONAL BUSINESS MACHINES CORPORATION, Armonk, NY (US); TOKYO ELECTRON LIMITED, Tokyo (JP)

(21) Appl. No.: 10/904,235

(22) Filed: Oct. 29, 2004

(51) Int. Cl. C23C 16/00; C23F 1/00; C03C 25/68

(52) U.S. Cl. 216/58; 118/724; 156/345.52

(57) ABSTRACT

An apparatus is provided which includes a holder operable to retain an article for interaction with a medium. The article has a first portion and a second portion, and the medium is such that the interaction alters the article in a temperature-dependent manner. First and second temperature-modifying elements are maintained by the holder adjacent to the first and second portions of the article to facilitate heat transfer between each temperature-modifying element and the adjacent portion of the article. The apparatus also includes a controller which is operable to maintain the first and second temperature-modifying elements at first and second independently controlled temperatures, respectively, such that the rate of interaction of the medium with each portion of the article is variable in a manner dependent upon the temperature of the adjacent temperature-modifying element.

### BACKGROUND OF THE INVENTION

The present invention relates to the processing of materials, especially the processing of microelectronic elements such as substrates and wafers.

Most semiconductor manufacturing processes strive to produce uniformity across a given wafer. For certain classes of reactions, process uniformity is readily achieved. In one example, an aqueous etching process is used to etch silicon dioxide, such etching process including a reagent such as aqueous hydrofluoric acid (HF). In such etching process, a holding element, known as a “boat”, contains approximately 25 wafers arranged in parallel. As held in the boat, the wafers are immersed in a fluid medium containing the aqueous reagent. In such processes, the reaction can produce uniform results across the wafer surface when the reaction time is long in comparison to the time needed for the fluid medium to wet the surface of the wafer upon immersing the wafers in the medium, and is also long in comparison to the time needed to subsequently rinse away the fluid medium from the wafer surface. In addition, for spatial process uniformity, the reaction should not consume so much of the reagent that the reagent becomes depleted in the volume between neighboring wafers.

In such aqueous etching processes, the immersion of the wafers in the fluid causes the surfaces of the wafers to quickly reach the temperature of the fluid. Spatial non-uniformity due to temperature gradients is not a concern. Because of the fluid immersion aspect of the process, conventional techniques are capable of maintaining the temperature of the fluid reservoir into which the wafers are immersed at a constant temperature. In any case, in such processes, there is no need to and generally no provision made for individually controlling the temperature of one wafer in the boat relative to another, or of one portion of a wafer relative to another portion of the same wafer.

In other types of processes, the reaction does not need to produce uniform results across the surface of the wafer or other substrate. Common neutral gaseous processes such as those used to strip away a photoresist material do not need to be spatially uniform across the wafer. Goals are satisfied as long as the resist is fully stripped from the entire wafer. Such goal is assured by performing the etching process for the amount of time expected to remove the resist from most areas of the wafer and then prolonging the process for a period of time in what is referred to as an “over-etch” step.

In some such processes, the over-etch step is so effective that some commercial reactors do not even attempt to uniformly distribute the gases which react with the resist. For example, in one such process, a plasma which is remote from the wafer is used to dissociate materials either into activated species which react with the photoresist material, and/or into neutral, uncharged radicals, such as atomic oxygen, CF4, and/or CHF3, among many others, which impinge on the photoresist layer to react with and remove the layer. After the activated species and/or the neutral radicals remove the resist material from the wafer, and in regions of the wafer not covered by resist, the underlying substrate is attacked by the activated species and/or the neutral radicals. In such process, damage to the underlying substrate can be avoided so long as the identity of the radicals is chosen carefully and if all ions are excluded from the reactive medium present at the wafer. If ions are present, then ion bombardment can damage the surface. For this reason, the source of the plasma which creates the active species is maintained at a distance far from the wafer surface so that ions created by the plasma dissociative process can fully recombine with electrons in the plasma before contacting the wafer.

For some processes involving neutral gaseous reactions, process uniformity is a requirement. For such processes to succeed, certain process constraints must be met, in that the temperature of the wafer or substrate must be maintained uniform across the entire surface, gases must be pumped at uniform rates, and reactive gases must be precisely distributed within the reaction chamber.

For example, U.S. Pat. Nos. 6,188,564 and 5,609,720 describe a way of increasing the uniformity of a reactive ion etch process by controlling the pressure of a gas supplied to different zones of the back side of a wafer during processing. A large amount of heat must be dissipated during reactive ion etch processes. The pressure is controlled in the different zones of the wafer in order to control the amount of heat transferred from the wafer to the chuck to produce more uniform results during processing.

In contrast to the above processes, which either provide spatial uniformity, or tolerate a great degree of non-uniformity, the inventors have discovered applications requiring controlled non-uniform, non-damaging, reactions between a neutral uncharged medium and a substrate. No available tooling satisfies such requirements.

In particular, a non-damaging oxide etching process is desired by which deliberate spatial non-uniformity can be achieved between different locations of the wafer. For example, such oxide etching process is desired for applications such as that referred to as “chemical oxide removal” (“COR”), a process which is used in particular applications to reduce the width of patterned hard mask patterns on a wafer, such as during “mask open” processes.

It would further be desirable to provide processing which can be controlled to a greater extent than that which is available according to conventional methods.

### SUMMARY OF THE INVENTION

According to one aspect of the invention, an apparatus is provided which includes a holder operable to retain an article for interaction with a medium. The article has a first portion and a second portion, and the medium is such that the interaction alters the article in a temperature-dependent manner. First and second temperature-modifying elements are maintained by the holder adjacent to the first and second portions of the article to facilitate heat transfer between each temperature-modifying element and the adjacent portion of the article. The apparatus also includes a controller which is operable to maintain the first and second temperature-modifying elements at first and second independently controlled temperatures, respectively, such that the rate of interaction of the medium with each portion of the article is variable in a manner dependent upon the temperature of the adjacent temperature-modifying element.

According to other aspects of the invention, a processing method and a recording medium having instructions recorded thereon for performing the processing method are provided. In such method, an article is retained for interaction with a medium. The article has a first portion and a second portion, and the medium is such that the rate of interaction varies in a temperature-dependent manner. First and second temperature-modifying elements are maintained adjacent to the first and second portions, respectively. Each temperature-modifying element is maintained at a different independently controlled temperature. In such way, the rate of interaction of the medium with each portion of the article varies in a manner dependent upon the temperature of the adjacent temperature-modifying element.

### BRIEF DESCRIPTION OF THE DRAWINGS

FIG. 1 is a block and exploded plan view illustrating an apparatus according to an embodiment of the invention.

FIG. 2 is a sectional view illustrating a chuck used in the apparatus of FIG. 1 according to an embodiment of the invention.

FIG. 3 is an elevational view of the chuck illustrated in FIG. 2.

FIG. 4 is a sectional view of a chuck according to an alternative embodiment of the invention.

FIG. 5 is a sectional view of a chuck according to yet another alternative embodiment of the invention.

FIG. 6 is an exploded plan view illustrating a wafer in relation to a member containing an array of heat transfer elements as utilized in an apparatus according to another embodiment of the invention.

### DETAILED DESCRIPTION

Among the advantages provided by some of the embodiments of the invention described herein is a way of deliberately causing spatial non-uniformity in the processing of an article such as a wafer. Such embodiments provide a way of precisely controlling the degree of spatial non-uniformity that is achieved. As one application of these principles, spatially non-uniform processing is provided by independently controlling the temperature of different zones of an article to restore spatial uniformity to an article which exhibits non-uniformity beforehand. In a particular embodiment described below, spatial non-uniformity is deliberately introduced into a chemical oxide removal (COR) process to correct for non-uniformity remaining after initial photolithographic exposure and patterning of an oxide layer. COR processing is particularly benefited because it is performed at low pressure, such that the temperature in different zones of the article can be controlled without being hampered by convection. In addition to the above, further embodiments of the invention are provided by which an article is processed by independently controlling temperatures of different portions of the article, such as under control of a programmed processor, for example. Alternatively, in other embodiments, spatially non-uniform processing is valuable in its own right to intentionally produce spatial non-uniformity in an article.

It is advantageous to use a precision method, as described herein, for controlling the temperature to control the rate of a reaction in processing such as COR, which operates by adsorbing gas onto the surface of the wafer. In fact, this reaction is the only gaseous reaction believed to require precise temperature control to within 0.1° C. tolerances to obtain best results. This need for precision requires precise ways of controlling the temperature, as provided according to the embodiments of the invention.

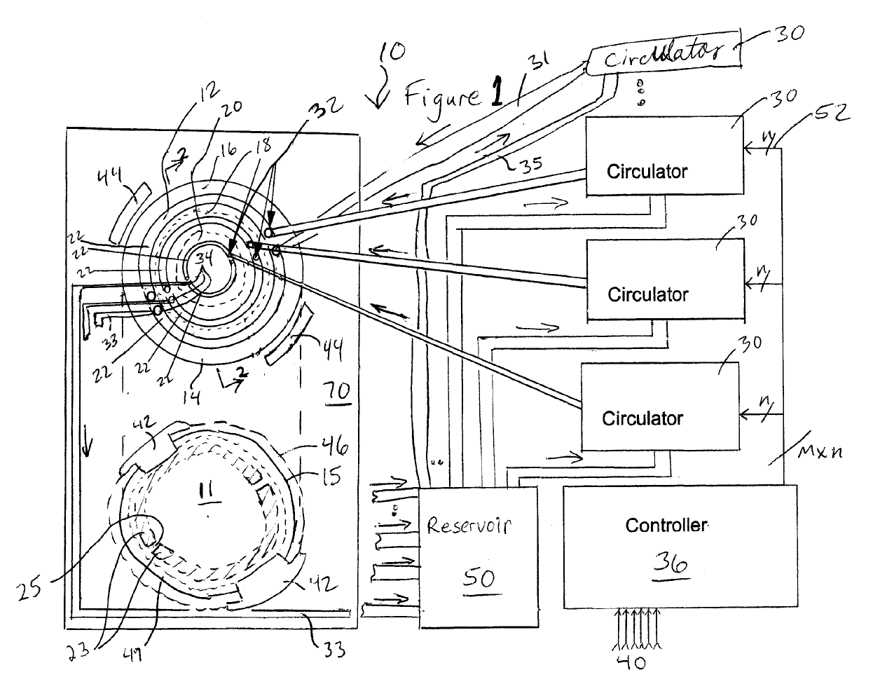

FIG. 1 is a block and exploded plan view illustrating an embodiment of the invention. In this embodiment, an arrangement is provided for deliberately establishing different temperatures in different zones of an article for processing within a chamber maintained at a low pressure. As shown in FIG. 1, an apparatus 10 is provided for processing an article 11, the article illustratively being a disk-shaped article such as a wafer or other substrate such as used in processing of microelectronic devices or other micro-scale devices such as micro-electromechanical (MEMs) devices. Reference is made to a wafer as an example of the article in the embodiments described herein, with the understanding that other types of articles can be processed, with appropriate modifications, by the apparatus or according to methods described herein. As shown in FIG. 1, the apparatus 10 includes a disk-shaped chuck 14 having clamp members 44 disposed along edges of the chuck. Alternatively, in a preferred embodiment, the wafer can be electrostatically chucked, such that it needs no mechanical members. The wafer 111 is maintained in fixed spatial relation to a chuck 14 by cooperating clamp members 42 which overlie edge portions 47 of the wafer. In an alternative embodiment, a clamp is provided as a ring 46 which overlies an outer edge 15 of the wafer so as to provide positive retention over a larger area than by use of the clamp members 42, 44.

Desirably, the chuck is formed of a thermally conductive material such as a metal, especially a CTE-matched metal such as molybdenum. Alternatively, the chuck 14 can be formed of a substantially rigid but thermally insulative material. For example, the chuck may be formed of one or more materials selected from ceramics, glasses, semiconductors, polymers, or combinations thereof such as carbon-polymer composites. When the chuck is formed of a material having a high modulus of elasticity such as a glass or ceramic, it is desirable to select the material to have a coefficient of thermal expansion (CTE) which is close to that of the wafer. Alternatively, a material which has a lower modulus of elasticity can be used which need not be as closely matched in CTE, since the chuck will then be expected to absorb some of the stresses from differential thermal expansion.

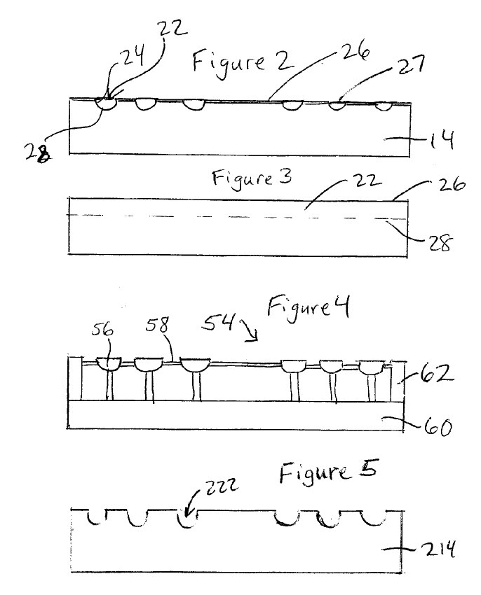

As further shown in FIG. 1, the chuck 14 has a plurality of fluid-carrying channels 22, each of which carries a fluid which is independently supplied by a temperature-controlled fluid circulator 30. The channels 22 serve as temperature-modifying elements for corresponding portions of the wafer 11 to which the fluid in each channel is flowed in thermal communication therewith. Thus, the channels 22 function to drive a fluid in proximity to one of the faces of the wafer to provide a heating and/or a cooling effect to portions of the wafer 111 to which they are closest. In this embodiment, to facilitate processes which are performed in a chamber at low pressure, a thermally conductive membrane 27 (FIG. 2), e.g., a thin metallic membrane, is disposed over each channel 22 to enclose the fluid in each channel. For best heat transfer between the wafer and the chuck 14, helium or other gas that does not interfere with processing the wafer is pumped into the space between the backside of the wafer and the metallic membrane. The fluid in each channel carries away heat from the portion of the wafer surface past which the membrane-covered channel runs. In such way, interaction is prevented between the fluid driven through the channels 22 for heat transfer purposes, and a medium 70 in the chamber used to process features of the wafer 11.

In the case of processing such as COR in which neutral radicals are generated from gaseous hydrogen fluoride (HF) and ammonia, there is minimal heat input to the wafer, and the reaction itself generates minimal heat. Consequently, the temperatures of different zones of the wafer can be easily altered by transferring heat between the different fluid-carrying channels of the chuck and the wafer.

As shown in FIG. 1, each channel 22 has substantially arcuate shape, i.e., each channel runs in a direction of an arc of a circle having a center which is the same or substantially the same as that of the chuck 14. Thus, each channel is arranged to carry the thermally conductive fluid past a corresponding arcuate portion of the wafer 11, for example, portion 23, such that the fluid carried by each channel independently modifies a temperature of that arcuate portion. In the particular example shown in FIG. 1, the chuck 14 includes six arcuate channels 22, which are disposed as three pairs of channels, each pair being disposed substantially in one of three concentric annular regions 16, 18, and 20 of the chuck 14. In the particular embodiment illustrated in FIG. 1, two independently controlled channels are disposed in each of the concentric annular regions 16, 18, 20. Thus, during processing, two channels 22 of the chuck are disposed adjacent to corresponding semi-circular portions 23 (shown with hatching for clarity) of one annular region 25 of the wafer 11. This arrangement allows different temperature gradients to be established in both a radial direction and along a particular diameter of the wafer. The channels can be disposed in other geometric arrangements, depending upon the temperature gradients desired to be established over the wafer.

As shown in the sectional view of FIG. 2 (which is taken through lines 2-2 of FIG. 1), the arcuate channels have sidewalls 24 extending downwardly from a major surface 26 of the chuck 14 to a bottom 28. Each channel 22 encloses an arcuate volume which extends in a direction parallel to the major surface 26 of the chuck 14. FIG. 3 is a side elevational view of the chuck 14 further illustrating the position of one of the channels 22. As shown therein, the bottom 28 of the channel 22 defines a line running beneath the major surface 26 in a direction parallel to the major surface of the chuck 14. In the preferred embodiment shown in FIGS. 1-3, each channel extends in a substantially semi-circular arc of a circle centered at the center of the wafer surface.

In a particular embodiment of the invention, as shown in FIG. 4, a chuck 54 is formed of one or more metals in which the channels extend as tubular members 56 which are held together structurally by bridges 58. The tubular members are mounted to a supporting member 60, which can be formed of a metal, for example. The tubular members are held structurally by an outer ring 62 of the chuck 54.

The particular interconnection and operation of the chuck together with the fluid circulator 30 will now be described. Each channel 22 of the chuck is connected to a fluid circulator 30 which pumps a fluid through the channel from an inlet 32 of the channel to an outlet 34 thereof. Each circulator 30 is capable of pumping a fluid through the channel 22 to which it is connected so as to maintain or modify a temperature of the region of the wafer to which the channel is closest. In one embodiment, the fluid includes a gas and/or a liquid having a capacity for transferring heat to or from the wafer. In one embodiment, the apparatus is designed to maintain the circulation of the fluid in liquid phase throughout closed circulation loops which include the circulators 30, supply tubing 31, channels 22, return tubing 33 from the channels to the reservoir 50, and return tubing 35 from the reservoir 50 to the circulators 30. Depending on whether the instantaneous temperature of the fluid inside the individual channel is higher or lower than the instantaneous temperature of the adjacent portion 23 of the wafer, the fluid either transfers heat towards a corresponding portion of the wafer or away from that portion of the wafer. Stated another way, the fluid either applies heat or cooling to the particular portion 23 of the wafer. Thus, the same channel 22 of the wafer can at one particular time apply heat to a portion of the wafer, and at another particular time, apply cooling to that same portion of the wafer.

In a particular embodiment, when the fluid is intended to provide significant cooling, and the region of the wafer is to be controlled to a temperature of between about −15° and +30° C., for example, the fluid may be one of several that has a boiling point at a temperature between about −15° and +15° C. In such way, the fluid provides cooling to the surface of the wafer 11 while undergoing a change from liquid phase to vapor phase. In such case, the fluid is drawn from a liquid reservoir 50, independently pumped into channels 22 of the chuck 14 and allowed to expand to a vapor phase or mixture of liquid and vapor phase, while absorbing heat from the surface of the wafer 11.

Each fluid circulator 30 is controlled independently from the other fluid circulators by a controller 36. The function of the controller is to control the operation of each fluid circulator 30 to establish and independently control the temperatures of portions of the article adjacent to the corresponding arcuate channels of the chuck 14. In a preferred embodiment, the controller 36 is feedback-driven, such that it seeks to minimize differences between temperature settings provided as input to the controller and temperature measurement signals 40 which represent the temperatures of at least some of the arcuate regions 16, 18 and 20 of the wafer 11. The feedback-driven controller 36 is desirably electrically actuated, the temperature measurement signals 40 preferably being electrical signals 40, e.g., from thermoelectric devices such as thermocouples (not shown) which are disposed either at or near the surface of the wafer. In addition, the controller 36 desirably controls the temperature of each arcuate region of the wafer 11 through one or more electrical signals 52 provided to each one of the fluid circulators 30.

In a particular embodiment, the controller 36 includes a programmable system, for example, a microcontroller or microprocessor. In one embodiment, the controller 36 includes a microprocessor, e.g., of a computer, which is capable of being programmed, as through use of a recording medium having instructions recorded thereon. Under program control, the microprocessor executes instructions to control the temperatures of each portion of the wafer adjacent to the chuck at one uniform temperature, or alternatively, to establish different independently controlled temperatures for each portion of the wafer. The program may provide for varying the temperatures of different portions of the wafer in relation to time, and may include cycling the different portions of the wafer through ranges of temperatures during processing.

In a particular embodiment, the controller 36 independently controls the flow rate of the fluid in each channel to establish independently controlled temperatures of each portion of the wafer. As described above, in one application of the apparatus 10, the controller can be programmed to set different target temperatures for each of the portions of the wafer, in order to deliberately cause temperature gradients across the wafer surface. Such might be the case when processes previously carried out have resulted in non-uniformity in the dimension of a feature at different locations of a wafer, such as the spatial non-uniformities described above as background to the present invention. In such case, the controller 36 can be programmed to cause the fluid circulators 30 to establish intentionally non-uniform temperatures at or near the surface of the wafer. The non-uniform reaction created by the intentionally non-uniform temperatures can then be designed to reduce or eliminate the non-uniformity in the dimension that was resulted from a previous process. Alternatively, the apparatus 10 can be used to reduce temperature gradients that are present across the wafer surface, to increase uniformity in processes which exhibit significant variations in relation to temperature.

With the wafer 11 mounted to apparatus 10, a medium is introduced which interacts with an exposed face of the wafer 11. In one embodiment, the medium 70 is applied to a front face of the wafer 11 to process features on the front face. The reactive medium can be a neutral gas, solid, liquid or solution which is applied directly or condensed or adsorbed from gaseous precursors onto the surface to be reacted. As one example, the medium may contain a reagent such as neutral radicals or an activated species which attacks a certain material present in features at the front face of the wafer. During such process, the apparatus 10 is used to apply the fluid through the chuck 14 (FIG. 2) to the surface of the membrane 27, or directly to the back face of the wafer 11 to establish temperature gradients between different locations of the wafer. Such use is especially advantageous for particular processes which result in spatial non-uniformity, e.g., in which radially outward portions of the wafer 11 interact, for instance, more slowly with the medium than those portions which are disposed closer to the center of the wafer 11. In that case, intentionally established differences in temperatures at the surfaces of the portions can be used to speed up the interactions between the medium and some of the portions, while maintaining the reaction rates the same or faster in other portions of the wafer. Ultimately, use of the apparatus 10 in this way permits a process having spatial non-uniformity to result in more uniform results of processing. For example, the apparatus 10 described herein can be used to produce more uniform results across the wafer surface in a process such as a chemical oxide removal (COR) process as described in the foregoing.

In yet another use of the apparatus, processing may have as a specific goal the production of a spatially non-uniform etching or deposition amount. In such case, the temperatures of the portions of the wafer surface may be controlled to establish intentionally different temperatures at each of the portions of the wafer. The intentionally non-uniform reaction can be used to compensate for variation in the size of like features across the wafer. The reaction can be tuned to etch the greatest in regions where the features are large, and to etch the least in regions where the features are small. In a preferred embodiment, a sensor is used to measure the degree of non-uniformity on the wafer and the information is transmitted to the controller 36 which calculates the wafer temperature distribution needed to compensate the variation in the feature size. The feature size can be measured prior to the wafer being chucked, or can be measured after the wafer is chucked but before the reaction takes place. For example, a scatterometer or ellipsometer can be used to process a return signal from targets disposed at different locations on the front surface of the wafer to determine the degree of non-uniformity that exists in the dimension of features which are present at a particular level, e.g., the surface level, of the wafer.

FIG. 5 is a sectional view illustrating a variation of a chuck 214 according to an embodiment of the invention. In this embodiment, the channels 222 are not covered by a membrane, but instead, remain open for delivering a fluid to the surface of the article being processed. Such embodiment can be used in processes such as fluid etching processes and other processes conducted at moderate or higher pressures in which direct interaction is desired between the fluid and the surface of the wafer. For example, the chuck 214 can be installed in an apparatus described above relative to FIG. 1 to deliver an etchant fluid at different temperatures to different zones of the front surface of a wafer during a wet etch process. Alternatively, the chuck 214 can be fixed to the back surface of the wafer for controlling temperatures of different zones of the wafer while the front surface is processed.

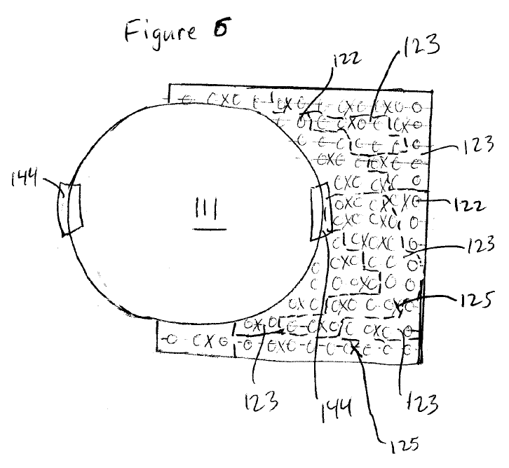

FIG. 6 illustrates another embodiment which is capable of providing a level of precision temperature control available in the above-described embodiments, but which is capable of controlling more zones of the wafer surface. As shown in FIG. 6, the wafer 111 is held in place by retaining members 144 above an array of individual heat transfer elements 122. Ideally, the heat transfer elements function as point sources for transferring heat either towards or away from one of the faces of the wafer. Many alternatives are available for implementing the heat transfer elements. Precision radiative sources may include an array of photo-emitter elements such as light-emitting diodes (LEDs) and/or lasers. The photo-emitter elements can be used as radiative sources to directly heat corresponding portions of the wafer, or, alternatively, to heat a fluid with which the wafer is in contact. Such photo-emitters can be cycled between on and off states to control the amount of heat reaching the wafer surface, according to the feedback-driven control provided by a control element such as controller 36 described above relative to FIG. 1. In a particular embodiment, the heat from a small number of lasers can be scanned across the surface of the wafer, such as through a mechanical carriage or an arrangement of optical elements, e.g., mirrors and lenses, the laser power being cycled intermittently so as to achieve localized heating of certain portions of one face of the wafer (i.e., most desirably, the back face). In such embodiment, the wavelength and other properties of the lasers are selected for best heating characteristics, and intentional defocus may be introduced to intentionally widen the size of the illuminated spot on the wafer to a dimension which gives rise to only modest temperature gradients.

The sources can heat different portions of the wafer surface differentially, according to the amount of power which can be supplied at different voltages to groups of the heat transfer elements 122, the voltages being controlled by a feedback-driven controller 36, such as described above with reference to FIG. 1. With the finer degree of control afforded thereby in heating portions of the wafer, the portions of the wafer which are uniformly heated are not constrained a priori to certain shapes and locations. Rather, in the embodiment shown in FIG. 6, the isothermic portions 123 can appear at locations and in shapes which are determined empirically during the processing of the wafer. In such embodiment, temperature sensors 125 are provided at many locations across the surface of the array, to monitor the temperature of a medium, e.g., a gas or fluid, which passes between the array of heat transfer elements 122 and the sensors 125.

In one embodiment, the front face of the wafer 111 may face towards the array of heat transfer elements 125, such that the interaction between the reactive medium occurs in the space between the front face and the array. Alternatively, the front face of the wafer 111 may face away from the array of heat transfer elements 125, and the wafer 111 be heated and/or cooled from the back face.

In yet another embodiment also providing precision temperature control, resistive heaters are utilized. Such heaters can be disposed in arcuate regions having the shapes such as the channels 22 described above with reference to FIG. 1. Alternatively, an array of heat transfer elements such as described relative to FIG. 6 can include such resistive heaters in place of or in addition to the aforementioned radiative sources. In yet another embodiment, both resistive heaters and channels carry a fluid having an independently controlled temperature.

In yet another embodiment also providing high precision temperature control, the heat transfer elements include Peltier modules. Peltier modules provide thermoelectric heating or cooling. Such modules include a pair of dissimilar materials, e.g., dissimilar metals or dissimilar semiconductors, e.g., p+ and n+ semiconductor types, through which a current is driven. When the current is present, heat is transferred from one side of an interface to another side of the interface. Thus, in one instance, a Peltier module provides heating to one side of the interface and in another instance, a Peltier module provides refrigeration to the other side of the interface. Peltier modules can be made very small because they are solid state devices. No fluid and no evacuated chamber are required to operate the module, such as required by an incandescent lamp. Thus, an embodiment is provided which includes an arrangement of Peltier modules having shapes such as the channels 22 described above relative to FIG. 1. Alternatively, in one embodiment, an array of such modules is provided, such as that described above with reference to FIG. 6.

Several of the aforementioned embodiments have an advantage of being controlled directly by electrical means instead of being controlled somewhat indirectly as in the case of the embodiments using fluid circulators.

While the invention has been described in accordance with certain preferred embodiments thereof, those skilled in the art will understand the many modifications and enhancements which can be made thereto without departing from the true scope and spirit of the invention, which is limited only by the claims appended below.

What is claimed is:

1. An apparatus, comprising:
means for retaining an article for interaction with a medium, the article having a first portion and a second portion, the medium being such that the interaction alters the article in a temperature-dependent manner; and
means for controlling a temperature of the first portion and for controlling a temperature of the second portion independently from the first portion to deliberately cause the rate of interaction between the medium and the article to differ in a controlled manner between the first and second portions of the article.

2. An apparatus, comprising:
a holder operable to retain an article for interaction with a medium, the article having a first portion and a second portion, the medium being such that the interaction alters the article in a temperature-dependent manner; and
first and second temperature-modifying elements maintained by the holder adjacent to the first and second portions of the article to facilitate heat transfer between each temperature-modifying element and the adjacent portion of the article; and
a controller operable to maintain the first and second temperature-modifying elements at first and second independently controlled temperatures, respectively, such that the rate of interaction of the medium with each portion of the article is variable in a manner dependent upon the temperature of the adjacent temperature-modifying element.

3. The apparatus as claimed in claim 2, wherein the article has a front face and a back face, the front face of the article being exposed to the medium, and the temperature-modifying elements being adjacent to at least one of the front face and the back face.

4. The apparatus as claimed in claim 3, wherein the temperature-modifying elements are disposed adjacent to the back face of the article.

5. The apparatus as claimed in claim 3, wherein the temperature-modifying elements are disposed adjacent to the front face of the article.

6. The apparatus as claimed in claim 3, wherein the controller includes a processor operable to control the temperature in each of the first and second portions in accordance with a program.

7. The apparatus as claimed in claim 3, wherein the first and second temperature-modifying elements include concentric elements to facilitate heat transfer between the temperature-modifying elements and concentrically disposed portions of the article.

8. The apparatus as claimed in claim 7, wherein the first temperature-modifying element includes first and second arc elements disposed at different positions of one circle, and the controller is operable to maintain the first and second arc elements at different independently controlled temperatures.

9. The apparatus as claimed in claim 8, wherein each arc element of each temperature-modifying element includes a closed channel adapted to conduct a fluid at the independently controlled temperature in proximity to the back face of the article, such that the medium interacts with arc portions of the article at rates dependent upon the temperatures of the fluid provided in each channel.

10. The apparatus as claimed in claim 8, wherein the medium includes a fluid and each arc element includes an open channel adapted to conduct the fluid at the independently controlled temperature onto the front face of the article such that the fluid contacts and interacts with arc portions of the article at rates dependent upon the temperatures of the fluid supplied from each channel.

11. The apparatus as claimed in claim 3, wherein each of the first and second temperature-modifying elements includes a plurality of radiative sources arranged in at least one of a linear pattern, a grid pattern, and an arc pattern.

12. The apparatus as claimed in claim 11, wherein the plurality of radiative sources include photo-emitters including at least one of light-emitting diodes (LEDs) and lasers, wherein the controller is operable to control an amount of heat applied by the photo-emitters by at least one of: (a) varying a number of the photo-emitters that are energized at positions adjacent to the first and second portions and (b) varying an output characteristic of the photo-emitters adjacent to the first and second portions.

13. A processing method, comprising:
retaining an article for interaction with a medium, the article having a first portion and a second portion, the medium being such that the rate of interaction varies in a temperature-dependent manner;
maintaining first and second temperature-modifying elements adjacent to the first and second portions, respectively; and
establishing each temperature-modifying element at a different independently controlled temperature,
whereby the rate of interaction of the medium with each portion of the article varies in a manner dependent upon the temperature of the adjacent temperature-modifying element.

14. The method as claimed in claim 13, wherein the article has a front face and a back face, the medium interacts with the article from the front face, and the temperature-modifying elements are disposed adjacent to the back face of the article.

15. The method as claimed in claim 14, wherein the front and back faces of the article define parallel planes, and the temperature-modifying elements have annular shape, such that the rates of interaction vary between respective annular portions of the article disposed adjacent to the temperature-modifying elements.

16. The method as claimed in claim 15, wherein two or more of the temperature-modifying elements are disposed in arcuate regions sharing a common center, such that the rates of interaction vary between corresponding arcuate regions of each annular portion of the article.

17. The method as claimed in claim 14, wherein each temperature-modifying element includes a channel adapted to carry a fluid, and the step of establishing the independently controlled temperature of the temperature-modifying element includes controlling the temperature of the fluid in the channel.

18. The method as claimed in claim 13, wherein the medium includes a fluid and each temperature-modifying element includes a channel adapted to carry the fluid to the front surface of the article, wherein the step of establishing the independently controlled temperature of the temperature-modifying element includes controlling the temperature of the fluid in the channel.

19. The method as claimed in claim 13, wherein the step of establishing each temperature-modifying element at different independently controlled temperatures includes transferring heat by at least one of resistive heating, radiative heating, and Peltier temperature control.

20. The method as claimed in claim 13, further comprising measuring a feature of the article, determining a degree of non-uniformity based on the step of measuring the feature, and establishing the different independently controlled temperatures of the temperature-modifying elements in accordance with the determined degree of non-uniformity.

21. A recording medium having instructions recorded thereon for performing a method to alter first and second portions of an article by interaction with a medium in a temperature-dependent manner, the method comprising:
maintaining first and second temperature-modifying elements adjacent to the first and second portions at different independently controlled temperatures, respectively,
whereby the rate of interaction of the medium with each portion of the article varies in a manner dependent upon the temperature of the adjacent temperature-modifying element.
